(19) United States
(12) Patent Application Publication
(10) Pub. No.: US 2025/0015144 A1
(43) Pub. Date: Jan. 9, 2025

(54) SUBSTRATE WITH ß-GALLIUM OXIDE FILM AND PRODUCTION METHOD THEREFOR

(71) Applicants: NATIONAL UNIVERSITY CORPORATION TOKAI NATIONAL HIGHER EDUCATION AND RESEARCH SYSTEM, Nagoya-shi (JP); AGC Inc., Tokyo (JP)

(72) Inventors: Masaru HORI, Nagoya-shi (JP); Osamu ODA, Nagoya-shi (JP); Arun Kumar DHASIYAN, Nagoya-shi (JP); Atsushi HAYASHI, Tokyo (JP); Nobutaka AOMINE, Tokyo (JP)

(73) Assignees: NATIONAL UNIVERSITY CORPORATION TOKAI NATIONAL HIGHER EDUCATION AND RESEARCH SYSTEM, Nagoya-shi (JP); AGC Inc., Tokyo (JP)

(21) Appl. No.: 18/894,828

(22) Filed: Sep. 24, 2024

Related U.S. Application Data
(63) Continuation of application No. PCT/JP2023/011020, filed on Mar. 20, 2023.

(30) Foreign Application Priority Data
Mar. 25, 2022 (JP) 2022-050538
Apr. 28, 2022 (JP) 2022-075480

(51) Int. Cl. H01L 29/26; C30B 25/10; C30B 25/18; C30B 29/06; C30B 29/16; H01L 21/02

(52) U.S. Cl. CPC H01L 29/26; C30B 25/105; C30B 25/186; C30B 29/06; C30B 29/16; H01L 21/02565; H01L 21/0262

(57) ABSTRACT

A substrate with a β-gallium oxide film includes a Si single crystal substrate and a β-gallium oxide film provided on the Si single crystal substrate. A substrate with a β-gallium oxide film includes a gallium nitride single crystal substrate and a β-gallium oxide film provided on the gallium nitride single crystal substrate.

### CROSS-REFERENCE TO RELATED APPLICATIONS

This is a bypass continuation of International Patent Application No. PCT/JP2023/011020, filed on Mar. 20, 2023, which claims priority to Japanese Patent Application No. 2022-050538, filed on Mar. 25, 2022, and Japanese Patent Application No. 2022-075480, filed on Apr. 28, 2022. The contents of these applications are hereby incorporated by reference in their entireties.

### TECHNICAL FIELD

The present invention relates to a substrate with a β-gallium oxide film, and particularly to a substrate with a β-gallium oxide film in which a β-gallium oxide film is provided on a Si single crystal substrate or a gallium nitride single crystal substrate. The present invention also relates to a method for producing a substrate with a β-gallium oxide film in which a β-gallium oxide film is provided on a single crystal substrate.

### BACKGROUND ART

Gallium oxide (Ga₂O₃) has various crystal structures, including α-type, β-type, γ-type, δ-type, and ε-type. Among these, a β-gallium oxide (β-Ga₂O₃) is a stable phase at a low temperature and a normal pressure. It is known that the β-gallium oxide is monoclinic in a crystal system, has a lattice constant of 12.214 Å in an a axis, i.e., a [100] axis, of 3.0371 Å in a b axis, i.e., a [010] axis, and of 5.7981 Å in a c axis, i.e., a [001] axis, and has an angle (β) between the a axis and the c axis of 103.83°. The β-gallium oxide has a band gap of about 4.5 eV to 4.9 eV, which is larger than a band gap of 3.26 eV of a 4H—SiC substrate and a band gap of 3.39 eV of GaN. Therefore, the β-gallium oxide is expected to be a semiconductor material having high breakdown strength.

For example, Patent Literature 1 discloses a technique of growing a β-gallium oxide single crystal film by supplying a gallium element from a first cell 13a in a vacuum tank 10 to a β-gallium oxide substrate 2, and supplying an oxygen gas containing ozone to the 1-gallium oxide substrate 2. In addition, Non Patent Literature 1 discloses a technique of treating an oxygen gas with rf-plasma in using a molecular beam epitaxy (MBE) device in order to grow a β-gallium oxide.

As other semiconductor materials, techniques have also been developed for heteroepitaxially growing a necessary semiconductor material on a Si substrate. For example, as for GaN, Non Patent Literature 2 discloses a technique of epitaxial growth on a Si (111) substrate via an AlN buffer layer using a method such as metal-organic chemical vapor deposition (MOCVD), which is also applied industrially.

Regarding the above, it is difficult to grow a gallium oxide on a dissimilar substrate. For example, studies have been conducted to grow a gallium oxide on a Si substrate by inserting a SiC buffer layer between the Si substrate and the gallium oxide in Non Patent Literature 3 and an Al₂O₃ buffer layer in Non Patent Literature 4, respectively. In addition, in Non Patent Literature 5 in which a gallium oxide is grown without a buffer layer, an amorphous gallium oxide layer is formed.

### CITATION LIST

### Patent Literature

Patent Literature 1: JP2013-56802A

### Non-Patent Literature

Non Patent Literature 1: Rf-plasma-assisted molecular-beam epitaxy of β-Ga₂O₃, E.G. Villora, et al., Appl. Phys. Lett. 88, 031105(2006)
Non Patent Literature 2: III-Nitride Based Lighting Emitting Diodes and Applications; Ch. 3 LEDs Based on Heteroepitaxial GaN on Si Substrates, T.E gawa and O. Oda, Springer Verlag, p. 27-58 (2013))
Non Patent Literature 3: Study of the Anisotropic Elastoplastic Properties of β-Ga₂O₃ Films Synthesized on SiC/Si Substrates, A. S. Grashchenko et al., Phys. Solid State, 60, 852-857(2018))
Non Patent Literature 4: β-Ga₂O₃ on Si (001) grown by plasma-assisted MBE with γ-Al₂O₃ (111) buffer layer: Structural characterization, T. Hadamek et al., AIP Advances, 11, 045209(2021))
Non Patent Literature 5: β-Ga₂O₃ MOSFETs on the Si substrate fabricated by the ion-cutting process, Y. B. Wang et al., Sci. China: Phys., Mech. Astron., 63, 277311(2020)

### SUMMARY OF INVENTION

### Technical Problem

Regarding the above, a gallium oxide film produced by a production apparatus in Patent Literature 1 is formed on a gallium oxide substrate rather than a dissimilar material substrate. Recently, it has become possible to produce a large-diameter gallium oxide at a low cost using an edge-defined film-fed growth (EFG) method, but the maximum diameter is still limited to 4 inches. Although the cost is lower than that in the related art, the gallium oxide substrate is still remarkably more expensive than other semiconductor substrates. Further, the gallium oxide film has a growth temperature as high as 700° C. or higher, and a growth rate as slow as about 0.1 m/h.

For these reasons, as long as the gallium oxide substrate is used to form a gallium oxide film, it is difficult to produce devices that can be industrialized. In addition, the gallium oxide produced by the above method has poor crystallinity, and there are also problems in flatness of the gallium oxide.

As shown in Non Patent Literature 2, techniques relating to heteroepitaxial growth have been developed for semiconductor materials other than a gallium oxide. On the other hand, as for the gallium oxide, a growth technique for semiconductor materials is still immature, and no good growth technique has been found yet. That is, the technique for heteroepitaxially growing a gallium oxide on a single crystal substrate made of a dissimilar material is still in development.

For example, in the techniques disclosed in the above Non Patent Literature 3 and Non Patent Literature 4, the gallium oxide is grown via a buffer layer, and it is not possible to grow a gallium oxide on a Si substrate without a buffer layer. In addition, the gallium oxide film has a growth temperature as high as 600° C. or higher, and the growth rate is slow. Further, the obtained gallium oxide film is not flat, has a domain structure, and has a low orientation property.

In addition, the gallium oxide film obtained by the method disclosed in the above Non Patent Literature 5 is an amorphous layer, and no crystalline layer is obtained.

As shown above, heteroepitaxial growth of a gallium oxide on a single crystal substrate made of a dissimilar material is very difficult and technically challenging.

Therefore, an object of the present invention is to provide a substrate with a β-gallium oxide film in which a β-gallium oxide film having an orientation property is provided on a Si single crystal substrate or a gallium nitride single crystal substrate. Another object of the present invention is to provide a novel production method for obtaining a substrate with a β-gallium oxide film in which a β-gallium oxide film having an orientation property is provided on a single crystal substrate.

### Solution to Problem

As a result of intensive studies on the above problems, the inventors of the present invention have found a method for forming a β-gallium oxide film having an orientation property on a single crystal substrate made of a dissimilar material rather than a gallium oxide. Thus, the present invention has been completed.

That is, the gist of the present invention is as follows.

[1] A substrate with a β-gallium oxide film, including: a Si single crystal substrate; and a β-gallium oxide film provided on the Si single crystal substrate,
in which the β-gallium oxide film is uniaxially oriented.

[2] The substrate with a β-gallium oxide film according to the above [1], in which the β-gallium oxide film is a single crystal.

[3] The substrate with a β-gallium oxide film according to the above [1] or [2], in which a peak of a β-gallium oxide that belongs to a (100) plane is observed by symmetrical X-ray diffraction.

[4] The substrate with a β-gallium oxide film according to the above [1] or [2], in which the β-gallium oxide film oriented in a (100) plane is provided on the Si single crystal substrate oriented in the (100) plane.

[5] The substrate with a β-gallium oxide film according to the above [1] or [2], in which a [001] direction of the Si single crystal substrate matches a [0-11] direction of the (3-gallium oxide film.

[6] The substrate with a β-gallium oxide film according to the above [1] or [2], in which the Si single crystal substrate and the β-gallium oxide film are in direct contact with each other.

[7] The substrate with a β-gallium oxide film according to the above [1] or [2], in which the β-gallium oxide film is provided on the Si single crystal substrate via at least one of a nucleation layer and a surface modification layer.

[8] The substrate with a β-gallium oxide film according to the above [1] or [2], in which the β-gallium oxide film has a thickness of 0.1 μm or more and 50 μm or less.

[9] A substrate with a β-gallium oxide film, including:
a gallium nitride single crystal substrate; and
a β-gallium oxide film provided on the gallium nitride single crystal substrate,
in which the β-gallium oxide film is uniaxially oriented.

[10] The substrate with a β-gallium oxide film according to the above [9], in which the β-gallium oxide film is a single crystal.

[11] The substrate with a β-gallium oxide film according to the above [9] or [10], in which a peak of a β-gallium oxide that belongs to a (100) plane is observed by symmetrical X-ray diffraction.

[12] The substrate with a β-gallium oxide film according to the above [9] or [10], in which the β-gallium oxide film oriented in a (100) plane is provided on the gallium nitride single crystal substrate oriented in a (0001) plane.

[13] The substrate with a β-gallium oxide film according to the above [9] or [10], in which the gallium nitride single crystal substrate and the β-gallium oxide film are in direct contact with each other.

[14] The substrate with a β-gallium oxide film according to the above [9] or [10], in which the β-gallium oxide film is provided on the gallium nitride single crystal substrate via at least one of a nucleation layer and a surface modification layer.

[15] The substrate with a β-gallium oxide film according to the above [9] or [10], in which the β-gallium oxide film has a thickness of 0.1 μm or more and 50 μm or less.

[16] A method for producing a substrate with a β-gallium oxide film, including:
providing a single crystal substrate in a reaction chamber;
generating plasma from a mixed gas containing oxygen and ozone to dissociate the ozone into oxygen constituent particles, and supplying the oxygen constituent particles to the reaction chamber under a reduced pressure;
supplying a gallium element to the reaction chamber; and
epitaxially growing a β-gallium oxide on the single crystal substrate.

[17] The method for producing a substrate with a β-gallium oxide film according to the above [16], in which a proportion of a lattice constant mismatch between the single crystal substrate and the epitaxially grown β-gallium oxide film is 15% or less.

[18] The method for producing a substrate with a β-gallium oxide film according to the above [16] or [17], in which as the single crystal substrate, a Si single crystal substrate, a gallium nitride single crystal substrate, or a sapphire single crystal substrate is used.

[19] The method for producing a substrate with a β-gallium oxide film according to the above [16] or [17], in which a surface of the single crystal substrate is subjected to an oxygen plasma treatment, and then the β-gallium oxide is epitaxially grown.

[20] The method for producing a substrate with a β-gallium oxide film according to the above [16] or [17], in which the β-gallium oxide is epitaxially grown at a film formation temperature of 600° C. or lower.

[21] The method for producing a substrate with a β-gallium oxide film according to the above [16] or [17], in which a concentration of the ozone is set to 10 vol % or more with respect to a total of the oxygen and the ozone in the mixed gas.

### Advantageous Effects of Invention

The present invention provides, for the first time, a substrate with a β-gallium oxide film uniaxially oriented on a single crystal substrate made of a dissimilar material. In addition, the above substrate with a β-gallium oxide film does not necessarily require a buffer layer made of a dissimilar material. In addition, the above substrate with a β-gallium oxide film not only has an orientation property, but also provides good crystallinity and film flatness.

The method for producing a substrate with a β-gallium oxide film according to the present invention not only provides a β-gallium oxide film having the above properties, but also provides a fast growth rate and allows use of a low growth temperature in heteroepitaxial growth of a β-gallium oxide. Therefore, it is expected that the method can be industrialized at a lower cost than that in the related art.

### BRIEF DESCRIPTION OF DRAWINGS

FIG. 1 is a schematic cross-sectional view showing a structure of a substrate with a β-gallium oxide film according to the present embodiment.

FIG. 2 is a schematic configuration diagram of a production apparatus used for producing the substrate with a β-gallium oxide film according to the present embodiment.

FIG. 3A and FIG. 3B show scanning electron microscope photographs of a surface of an obtained Si single crystal substrate with a β-gallium oxide film. FIG. 3A is a photograph at a magnification of 5,000 times, and FIG. 3B is a photograph at a magnification of 100,000 times.

FIG. 4A and FIG. 4B show scanning electron microscope photographs of a cross section of the obtained Si single crystal substrate with a β-gallium oxide film. FIG. 4A is a photograph at a magnification of 10,000 times, and FIG. 4B is a photograph at a magnification of 20,000 times.

FIG. 5 is a symmetrical X-ray diffraction pattern of the obtained Si single crystal substrate with a β-gallium oxide film.

FIG. 6 is an in-plane X-ray diffraction pattern of the obtained Si single crystal substrate with a β-gallium oxide film.

FIG. 7A and FIG. 7B show atomic force microscope (AFM) images of the surface of the obtained Si single crystal substrate. FIG. 7A is an AFM image of the Si single crystal substrate before an oxygen plasma treatment is performed, and FIG. 7B is an AFM image of the Si single crystal substrate after the oxygen plasma treatment for 15 minutes is performed.

### DESCRIPTION OF EMBODIMENTS

Hereinafter, the present invention is described in detail, but the present invention is not limited to the following embodiment and can be freely modified and implemented without departing from the gist of the present invention.

In the present description, a single crystal substrate means a substrate in which the entire substrate is a single crystal.

In the present description, the “uniaxially oriented” means that there are many crystal grains each having at least one of crystal axes aligned in one axis direction, and refers to a state where there are many crystal grains that are rotated around this axis. The uniaxial orientation of the β-gallium oxide film can be checked, for example, by symmetrical X-ray diffraction (symmetrical XRD).

In the present description, oxygen constituent particles are particles containing oxygen atoms, including a singlet oxygen atom and a triplet oxygen atom, an oxygen molecule, ozone, or excited states thereof.

In the present description, “to” indicating a numerical range is used in the sense of including the numerical values set forth before and after the “to” as a lower limit value and an upper limit value.

<Substrate with β-Gallium Oxide Film>

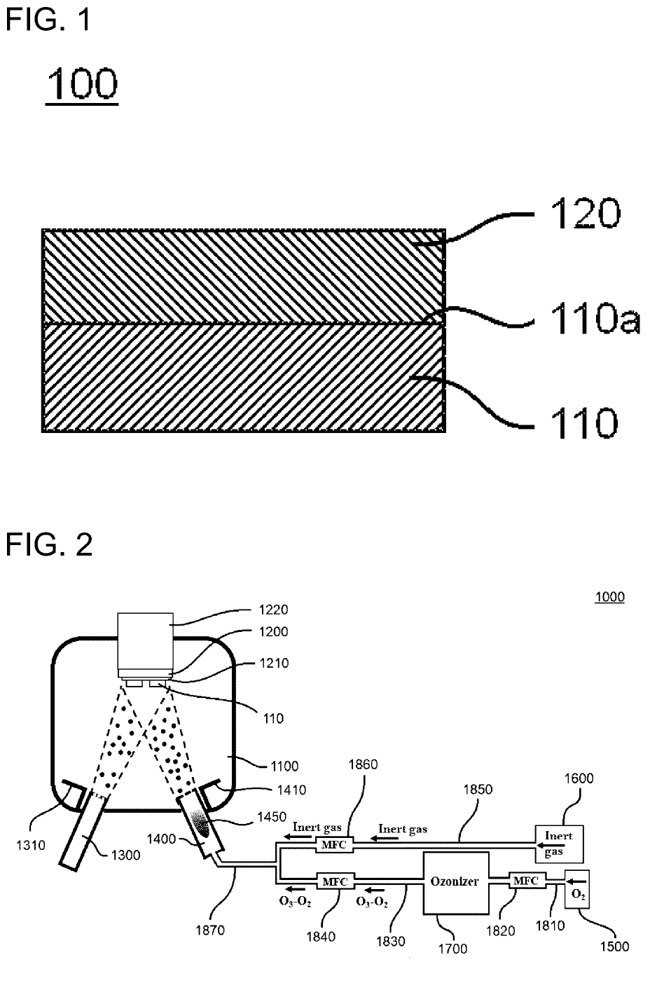

As shown in FIG. 1, a substrate with a β-gallium oxide film 100 according to the present embodiment includes a single crystal substrate 110, and a β-gallium oxide film 120 provided on the above single crystal substrate 110, and the β-gallium oxide film 120 is uniaxially oriented.

It is sufficient that the β-gallium oxide film 120 is provided on at least one of main surfaces of the single crystal substrate 110, that is, on at least a first main surface 110a, and may be provided on both main surfaces. However, from the viewpoint of epitaxially growing the 3-gallium oxide film 120, the β-gallium oxide film 120 is preferably provided only on the first main surface 110a.

The case where a Si single crystal substrate and a gallium nitride single crystal substrate are used as the above single crystal substrate is described below.

(Si Single Crystal Substrate with β-Gallium Oxide Film)

A Si single crystal substrate with a β-gallium oxide film according to the present embodiment includes a Si single crystal substrate, and a β-gallium oxide film provided on the above Si single crystal substrate, and the β-gallium oxide film is uniaxially oriented.

As the Si single crystal substrate, those known in the related art can be used. For example, a substrate that has been subjected to crystal growth using a Czochralski method or a floating zone (FZ) method and cut and polished can be used.

The Si single crystal substrate is preferably a substrate oriented in a (100) plane, and a main surface oriented in the (100) plane is preferably used as the first main surface, on which a β-gallium oxide film is provided.

The β-gallium oxide film is a film epitaxially grown on the Si single crystal substrate, preferably on the (100) plane of the Si single crystal substrate, and is uniaxially oriented.

The β-gallium oxide film may be either a single crystal or a polycrystal, and is preferably a single crystal or a crystal close to a single crystal, and more preferably a single crystal, from the viewpoint of a yield and properties of a semiconductor device.

In the case where a few impurities are mixed in to grow an n-type or p-type gallium oxide semiconductor, the β-gallium oxide film may contain the impurities.

Note that, in the present description, whether the β-gallium oxide film is a single crystal film can be measured, for example, by a crystal X-ray diffraction (XRD) apparatus using CuKα rays as a ray source. When it is a single crystal, an XRD pattern specific to the single crystal can be obtained.

In the case where the β-gallium oxide film is a single crystal, the β-gallium oxide film is, for example, preferably a film oriented in the (100) plane, and more preferably, a β-gallium oxide film oriented in the (100) plane is provided on a Si single crystal substrate oriented in the (100) plane.

In the Si single crystal substrate with a β-gallium oxide film according to the present embodiment, examples of an index of crystallinity of a β-gallium oxide single crystal film include presence or absence of a peak of the β-gallium oxide that belongs to the (100) plane by symmetrical X-ray diffraction. When the same peak is observed, heteroepitaxial growth can be confirmed. Examples of the peak of the β-gallium oxide that belongs to the (100) plane include peaks of a (400) plane, a (600) plane, and a (800) plane.

Symmetrical X-ray diffraction measurement is performed, for example, by using CuKα rays as a ray source, irradiating a surface of the Si single crystal substrate with X-rays at an incident angle of a Bragg diffraction angle θ, and rotating a detector to detect the diffracted X-rays at θ-2θ. In a symmetrical X-ray diffraction pattern obtained by such measurement, a diffraction peak is obtained for the Ga₂O₃ (400) plane at a Bragg diffraction angle of 2θ=30.07° and for the Ga₂O₃ (600) plane at a Bragg diffraction angle of 2θ=44.7°. Therefore, when a diffraction peak is obtained at the above Bragg diffraction angle, it can belong to the peak of the (100) plane of the β-gallium oxide.

As a relationship between crystal orientations of the Si single crystal substrate and the β-gallium oxide film, a [001] direction of the Si single crystal substrate preferably matches a [0-11] direction of the β-gallium oxide film, from the viewpoint of an epitaxial relationship.

The orientation of the Si single crystal substrate and the β-gallium oxide film can be understood by using in-plane X-ray diffraction.

The expression “the [001] direction of the Si single crystal substrate matches the [0-11] direction of the β-gallium oxide film” means that the two directions are not necessarily completely match each other, and it is sufficient that the two directions substantially match each other. That is, as a result of the in-plane X-ray diffraction, when an angle formed between the [001] direction of the Si single crystal substrate and the [001] direction of the β-gallium oxide film is about 23° to 28°, it can be said that the [001] direction of the Si single crystal substrate substantially matches the [0-11] direction of the β-gallium oxide film.

Note that, in the above in-plane X-ray diffraction, a proportion of a lattice constant mismatch, called lattice mismatch, can also be quantified.

In the Si single crystal substrate with a β-gallium oxide film according to the present embodiment, the β-gallium oxide film is provided on the Si single crystal substrate without a buffer layer. The buffer layer is a layer inserted mainly for the purpose of reducing the lattice constant mismatch, and generally has a thickness of 20 nm or more. However, the Si single crystal substrate with a β-gallium oxide film according to the present embodiment does not in any way exclude an embodiment in which a buffer layer is included.

The Si single crystal substrate with a β-gallium oxide film according to the present embodiment does not necessarily require a buffer layer, and a preferred embodiment thereof include a Si single crystal substrate with a β-gallium oxide film in which the Si single crystal substrate and the β-gallium oxide film are in direct contact with each other.

Also preferred is an embodiment in which the β-gallium oxide film is provided on the Si single crystal substrate via at least one of a nucleation layer and a surface modification layer.

The nucleation layer or the surface modification layer is a layer provided for the purpose of promoting crystallization of the β-gallium oxide, and is different from the buffer layer in the viewpoint of crystallinity.

The buffer layer refers to, for example, a single crystal film made of a corresponding material having a predetermined thickness, a layer formed by gradually changing a composition of a mixed crystal of the corresponding material and a dissimilar material, or a layer grown as a superlattice structure of the corresponding material and a different material.

On the other hand, the nucleation layer is a layer inserted for the purpose of promoting the crystallization of the β-gallium oxide, and refers to an adsorption layer or a thin film having a lattice constant different from that of the corresponding material. The nucleation layer has a thickness of, for example, less than 20 nm, preferably less than 10 nm, and more preferably less than 5 nm.

The nucleation layer may be a continuous layer or a discontinuous layer. The presence of the nucleation layer can be determined based on differences in atomic arrangements observed through cross-sectional transmission electron microscope (TEM). In the case where no change in atomic arrangement is observed, it can be determined that the Si single crystal substrate and the β-gallium oxide film are in direct contact with each other.

Examples of the nucleation layer include a layer containing an element different from that of the substrate, or a surface modification layer formed by modifying the surface of the substrate. That is, the surface modification layer is a layer obtained by modifying a surface of a substrate such as a single crystal substrate, and has a different lattice constant from that of the corresponding material.

The β-gallium oxide film has a thickness of preferably 0.1 μm to 50 μm, more preferably 0.5 μm to 50 μm, still preferably 0.8 μm to 30 μm, and particularly preferably 1 m to 20 μm. Here, from the viewpoint of application to a power device and the like, the above thickness of the β-gallium oxide film is preferably 0.1 μm or more, more preferably 0.5 μm or more, still more preferably 0.8 μm or more, and particularly preferably 1 μm or more. In addition, an upper limit thereof is not particularly limited, and from the viewpoint of a film formation rate and a film quality, the thickness of the β-gallium oxide film is preferably 50 m or less, more preferably 30 μm or less, and still more preferably 20 μm or less. Note that, the above thickness can be measured by using a scanning electron microscope or the like for a cross section of the Si single crystal substrate with a β-gallium oxide film.

The proportion of the lattice constant mismatch between the Si single crystal substrate and the β-gallium oxide film is preferably 15% or less, more preferably 12% or less, and still more preferably 8% or less. The above proportion is preferably lower, and is generally more than 0%.

The proportion of the lattice constant mismatch is determined by analyzing the epitaxial relationship of the β-gallium oxide film on the Si single crystal substrate based on results of the symmetrical X-ray diffraction measurement and the in-plane X-ray diffraction measurement. Note that, the lattice constant mismatch is a ratio of a difference between a lattice constant of the Si single crystal substrate and a lattice constant of the β-gallium oxide film in the same direction, and as to be described later, can be calculated, for example, based on a ratio between the lattice constant of the Si single crystal substrate and the lattice constant of the 3-gallium oxide single crystal film projected onto a certain direction of the Si single crystal substrate.

(Gallium Nitride Single Crystal Substrate with β-Gallium Oxide Film)

A gallium nitride single crystal substrate with a β-gallium oxide film according to the present embodiment includes a gallium nitride single crystal substrate, and a β-gallium oxide film provided on the above gallium nitride single crystal substrate, and the β-gallium oxide film is uniaxially oriented.

As the gallium nitride single crystal substrate, those known in the related art can be used. For example, a substrate that has been subjected to crystal growth by a halide vapor phase epitaxy (HVPE) method, a supercritical acidic ammonia technology (SCAAT) method, a low-pressure acidic ammonothermal (LPAAT) method, a Na flux method, or the like, and cut and polished, and substrates obtained by heteroepitaxially growing a gallium nitride on a sapphire single crystal substrate or a Si single crystal substrate can be used.

The gallium nitride single crystal substrate is preferably a substrate oriented in a (0001) plane, and a main surface oriented in the (0001) plane is preferably used as the first main surface, on which a β-gallium oxide film is provided.

The β-gallium oxide film is a film epitaxially grown on the gallium nitride single crystal substrate, preferably on the (0001) plane of the gallium nitride single crystal substrate, and is uniaxially oriented.

The β-gallium oxide film may be either a single crystal or a polycrystal, is preferably a single crystal or a crystal close to a single crystal, and more preferably a single crystal, from the viewpoint of a semiconductor application.

In the case where a few impurities are mixed in to grow an n-type or p-type gallium oxide semiconductor, the β-gallium oxide film may contain the impurities.

In the case where the β-gallium oxide film is a single crystal, the β-gallium oxide film is, for example, preferably a film oriented in the (100) plane, and more preferably, a β-gallium oxide film oriented in the (100) plane is provided on a gallium nitride single crystal substrate oriented in the (0001) plane.

In the gallium nitride single crystal substrate with a β-gallium oxide film according to the present embodiment, examples of an index of crystallinity of a β-gallium oxide single crystal film include presence or absence of a peak of the β-gallium oxide that belongs to the (100) plane by symmetrical X-ray diffraction. When the same peak is observed, heteroepitaxial growth can be confirmed. Examples of the peak of the β-gallium oxide that belongs to the (100) plane include peaks of a (400) plane, a (600) plane, and a (800) plane.

The peak of the β-gallium oxide that can belong to the (100) plane by symmetrical X-ray diffraction is the same as the peak described in the above (Si Single Crystal Substrate with β-gallium Oxide Film).

In the gallium nitride single crystal substrate with a β-gallium oxide film according to the present embodiment, the β-gallium oxide film is provided on the gallium nitride single crystal substrate without a buffer layer. However, the gallium nitride single crystal substrate with a β-gallium oxide film according to the present embodiment does not in any way exclude an embodiment in which a buffer layer is included. In addition, the buffer layer is the same as the buffer layer in the above Si single crystal substrate with a β-gallium oxide film.

The gallium nitride single crystal substrate with a β-gallium oxide film according to the present embodiment does not necessarily require a buffer layer, and a preferred embodiment thereof include a gallium nitride single crystal substrate with a β-gallium oxide film in which the gallium nitride single crystal substrate and the β-gallium oxide film are in direct contact with each other.

Also preferred is an embodiment in which the β-gallium oxide film is provided on the gallium nitride single crystal substrate via at least one of a nucleation layer and a surface modification layer.

The nucleation layer and the surface modification layer are the same as the nucleation layer and the surface modification layer in the above Si single crystal substrate with a β-gallium oxide film, and the preferred embodiments are also the same.

The β-gallium oxide film has a thickness of preferably 0.1 μm to 50 μm, more preferably 0.5 μm to 50 μm, still preferably 0.8 μm to 30 μm, and particularly preferably 1 m to 20 m. Here, from the viewpoint of withstand voltage for application to a power device and the like, the thickness of the β-gallium oxide film is preferably 0.1 μm or more, more preferably 0.5 μm or more, still more preferably 0.8 μm or more, and particularly preferably 1 μm or more. In addition, an upper limit thereof is not particularly limited, and from the viewpoint of a film formation rate and a film quality, the thickness of the β-gallium oxide film is preferably 50 m or less, more preferably 30 μm or less, and still more preferably 20 μm or less.

The proportion of the lattice constant mismatch between the gallium nitride single crystal substrate and the β-gallium oxide film is preferably 15% or less, and more preferably 10% or less. The above proportion is preferably lower, and is generally more than 0%.

<Method for Producing Substrate with β-Gallium Oxide Film>

A method for producing a substrate with a β-gallium oxide film according to the present embodiment includes the following step 1 to step 4.

Step 1: a step of providing a single crystal substrate in a reaction chamber

Step 2: a step of generating plasma from a mixed gas containing oxygen and ozone to dissociate ozone into oxygen constituent particles, and supplying the oxygen constituent particles to the reaction chamber under a reduced pressure

Step 3: a step of supplying a gallium element to the reaction chamber, along with the step 2

Step 4: a step of epitaxially growing a β-gallium oxide on the single crystal substrate

Before describing each step, one embodiment of a production apparatus to be used is described with reference to FIG. 2. Note that, the production apparatus to be used in the production method according to the present embodiment is not limited to the following.

### (Production Apparatus)

In the production method according to the present embodiment, for example, a production apparatus 1000 shown in a schematic configuration diagram in FIG. 2 can be used.

The production apparatus 1000 includes a reaction chamber 1100, a substrate disposition portion 1200, a gallium element supply device 1300, an oxygen element supply device 1400, and a heating device 1220.

The reaction chamber 1100 is a place where a β-gallium oxide film is epitaxially grown on the single crystal substrate 110. The reaction chamber 1100 includes the substrate disposition portion 1200 and a susceptor 1210 therein, the single crystal substrate 110 is disposed on the substrate disposition portion 1200, and the single crystal substrate 110 is supported by a susceptor 1210.

The substrate disposition portion 1200 in the reaction chamber 1100 can be heated by the heating device 1220, and the single crystal substrate 110 can be set to a desired temperature. With the heating device, a temperature of the substrate disposition portion 1200 can be set to 0° C. or higher, and preferably to room temperature or higher. In addition, an upper limit of the heating temperature is not particularly limited, and it is sufficient if the heating temperature can be up to 700° C., for example.

The gallium element supply device 1300 supplies a gallium element (Ga) to the disposed single crystal substrate 110. The gallium element supply device 1300 is not particularly limited as long as it can supply a gallium element, and may be, for example, a Knudsen cell.

In the case of a Knudsen cell, the gallium element supply device 1300 includes a shutter 1310, which thereby allows or blocks communication between the gallium element supply device 1300 and the reaction chamber 1100. The gallium element supply device 1300 may include a heating device or a cooling device.

In addition, the oxygen element supply device 1400 supplies oxygen constituent particles to the disposed single crystal substrate 110. The oxygen element supply device 1400 includes a plasma generation unit 1450 and, if necessary, a shutter 1410. The shutter 1410 allows or blocks communication between the oxygen element supply device 1400 and the reaction chamber 1100. The oxygen element supply device 1400 may include a heating device or a cooling device.

The oxygen constituent particles supplied to the single crystal substrate 110 by the oxygen element supply device 1400 are obtained by generating plasma from a mixed gas containing oxygen and ozone by the plasma generation unit 1450 to dissociate ozone.

Specifically, an oxygen gas is supplied from an oxygen gas supply unit 1500 to the oxygen element supply device 1400. The oxygen gas passes through an oxygen gas supply pipe 1810 and flows into the ozonizer 1700 while a flow rate thereof is adjusted by a mass flow controller 1820.

The oxygen gas that flows into the ozonizer 1700 is partially converted into ozone, to obtain a mixed gas containing oxygen and ozone. Examples of such an ozonizer 1700 include a first plasma generation device that generates plasma from an oxygen gas.

The ozonizer 1700 has a capacity of setting a concentration of ozone to preferably 10 vol % or more, more preferably 20 vol % or more, and still more preferably 25 vol % or more, with respect to a total of oxygen and ozone.

The mixed gas containing oxygen and ozone generated by the ozonizer 1700 passes through an ozone-oxygen mixed gas supply pipe 1830 and flows into the oxygen element supply device 1400 while a flow rate thereof is adjusted by a mass flow controller 1840.

Note that, the ozonizer 1700 and the oxygen element supply device 1400 may be directly connected to each other, and in this case, the ozone-oxygen mixed gas supply pipe 1830 and the mass flow controller 1840 are not necessary.

In addition to the above mixed gas containing oxygen and ozone, an inert gas is supplied to the oxygen element supply device 1400 from an inert gas supply unit 1600. Examples of the inert gas include a rare gas such as an Ar gas or a He gas. However, since plasma generation to be described later is possible without an inert gas when a mixed gas containing oxygen and ozone is present, the supply of the inert gas is optional.

The inert gas passes through an inert gas supply pipe 1850 from the inert gas supply unit 1600 and flows into the oxygen element supply device 1400 while a flow rate thereof is adjusted by a mass flow controller 1860.

The above mixed gas containing oxygen and ozone and the inert gas may be separately introduced into the oxygen element supply device 1400. As shown in FIG. 2, both gases may flow into the mixed gas supply pipe 1870 and may be supplied to the oxygen element supply device 1400 in a mixed state. That is, the mixed gas supply pipe 1870 is a pipe for supplying a gas in which the mixed gas containing oxygen and ozone for generating plasma in the oxygen element supply device 1400 and the inert gas are mixed.

Note that, in the case where a mixed gas for generating plasma does not contain an inert gas, the above inert gas supply unit 1600, inert gas supply pipe 1850, and mass flow controller 1860 are not necessary.

In addition to the above, the production apparatus 1000 may also include an impurity element supply unit (not shown) that supplies an impurity. The impurity element supply unit supplies an impurity element to grow an n-gallium oxide or a p-type gallium oxide.

### (Step 1)

In the step 1, a single crystal substrate 110 is provided in a reaction chamber 1100. That is, the single crystal substrate 110 is placed on the substrate disposition portion 1200 and supported by the susceptor 1210. Then, the substrate disposition portion 1200 is heated using the heating device 1220 to heat the single crystal substrate 110 to a desired temperature, and a pressure in the reaction chamber 1100 is reduced in preparation for the subsequent step 2.

Note that, the internal pressure of the reaction chamber 1100 and the temperature of the substrate disposition portion 1200, that is, the temperature of the single crystal substrate 110, are preferably set to an internal pressure and a temperature to be described later in (Step 4).

The single crystal substrate 110 is preferably a Si single crystal substrate, a gallium nitride single crystal substrate, or a sapphire single crystal substrate. In addition, single crystal substrates made of various oxides and a SiC single crystal substrate may be used. Examples of the oxide include MgO, MgAl₂O₄, SrTiO₃, and ZrO₂.

Before being subjected to the subsequent step 2, the single crystal substrate 110 may have a nucleation layer or a surface modification layer formed on the surface, or a β-gallium oxide film may be formed directly on the surface of the single crystal substrate 110.

When the nucleation layer or the surface modification layer is formed, the β-gallium oxide film is easier to grow.

In the case of forming the surface modification layer, for example, the surface of the single crystal substrate 110 may be subjected to an oxygen plasma treatment. The oxygen plasma treatment is a surface treatment performed using a gas obtained by generating plasma from a mixed gas containing oxygen and ozone to dissociate the above ozone into oxygen constituent particles.

In addition, a nucleation layer made of a dissimilar material may be formed on the surface of the single crystal substrate 110. In this case, examples of the dissimilar material include SiO₂, Si₃N₄, Al₂O₃, In₂O₃, AlN, GaN, and InN.

### (Step 2)

In the step 2, plasma is generated from a mixed gas containing oxygen and ozone to dissociate ozone into oxygen constituent particles, and the oxygen constituent particles are supplied to the above reaction chamber 1100 under a reduced pressure.

Specifically, as described above, a portion of the oxygen gas supplied from the oxygen gas supply unit 1500 to the ozonizer 1700 is subjected to a plasma treatment by using first plasma generated in the ozonizer 1700 to be ozone, thereby obtaining a mixed gas containing oxygen and ozone. The mixed gas is supplied to the oxygen element supply device 1400 through the mixed gas supply pipe 1870.

The ozonizer 1700 sets the concentration of ozone to preferably 10 vol % or more, more preferably 20 vol % or more, and still more preferably 25 vol % or more, with respect to the total of oxygen and ozone. An upper limit of the volume is not particularly limited, and is generally 50 vol % or less.

If desired, an inert gas such as an Ar gas is supplied from the inert gas supply unit 1600 through the mixed gas supply pipe 1870 to the oxygen element supply device 1400. In this case, the mixed gas containing oxygen and ozone and the inert gas are mixed in the mixed gas supply pipe 1870 to obtain a mixed gas containing oxygen, ozone, and an inert gas.

As for a proportion for mixing the mixed gas containing oxygen and ozone and the inert gas, in the case where the mixed gas containing oxygen and ozone is 100 parts by volume, the proportion of the inert gas is preferably 230 to 1900 parts by volume, more preferably 230 to 1500 parts by volume, still more preferably 350 to 1000 parts by volume, and even more preferably 350 to 460 parts by volume. Here, from the viewpoint of plasma ignition, the above proportion of the inert gas is preferably 230 parts by volume or more, and more preferably 350 parts by volume or more. In addition, from the viewpoint of a density of an oxygen radical, the above proportion of the inert gas is preferably 1900 parts by volume or less, more preferably 1500 parts by volume or less, still more preferably 1000 parts by volume or less, and even more preferably 460 parts by volume or less.

It is thought that, in the mixed gas supplied to the oxygen element supply device 1400 through the mixed gas supply pipe 1870, ozone is decomposed by using second plasma generated by the plasma generation unit 1450 in the oxygen element supply device 1400, and an oxygen molecule and an oxygen radical, which contain a large quantity of singlet oxygen atoms O (¹D) and have a strong oxidizing power, are generated. Here, the above oxygen radical contains a singlet oxygen atom O (¹D) and a triplet oxygen atom O (³P). The singlet oxygen atom O (¹D) transitions to the triplet oxygen atom O (³P) at a certain rate.

In this way, ozone dissociated into oxygen molecules and oxygen radicals is called oxygen constituent particles, which are supplied to the reaction chamber 1100 under a reduced pressure. Note that, it is not excluded in any way that not only the oxygen constituent particles but also the mixed gas containing oxygen and ozone that has not been converted into plasma is supplied to the reaction chamber 1100 under a reduced pressure.

### (Step 3)

In the step 3, along with the above step 2, a gallium element is supplied to the above reaction chamber 1100 under a reduced pressure.

That is, the gallium element (Ga) is supplied from the gallium element supply device 1300 to the reaction chamber 1100 under a reduced pressure. As a result, the supplied Ga reacts with the oxygen radical and the like provided in the step 2 on the surface of the single crystal substrate 110, generating a flat β-gallium oxide film on the surface of the single crystal substrate 110.

Specifically, near the surface of the single crystal substrate 110, Ga reacts with the singlet oxygen atom or the triplet oxygen atom O (³P) resulting from transition of the singlet oxygen atom O (¹D) to grow the β-gallium oxide film. When many singlet oxygen atoms or triplet oxygen atoms O (³P) resulting from transition of the singlet oxygen atoms O (¹D) reach the surface of the single crystal substrate 110, a β-gallium oxide film having excellent crystallinity and good flatness is grown. A film formation rate for the β-gallium oxide film is faster than a film formation rate for a β-gallium oxide film in the case of using a production apparatus in the related art.

In the step 2, a pressure of the gas supplied from the oxygen element supply device 1400 containing oxygen constituent particles is preferably 1.0×10⁻⁵ Pa to 1.0×10⁻¹ Pa, more preferably 1.0×10⁻⁴ Pa to 1.0×10⁻¹ Pa, and still more preferably 1.0×10⁻³ Pa to 1.0×10⁻² Pa. Here, from the viewpoint of supplying sufficient oxygen radicals, the above gas pressure is preferably 1.0×10⁻⁵ Pa or more, more preferably 1.0×10⁻⁴ Pa or more, and still more preferably 1.0×10⁻³ Pa or more. In addition, from the viewpoint of generating oxygen radicals, in the step 2, the pressure of the gas supplied from the oxygen element supply device 1400 containing oxygen constituent particles is preferably 1.0×10⁻¹ Pa or less, and more preferably 1.0×10⁻² Pa or less.

In the step 3, a pressure of the gas supplied from the gallium element supply device 1300 is preferably 1.0×10⁻⁵ Pa to 1.0×10⁻² Pa, more preferably 5.0×10⁻⁵ Pa to 1.0×10⁻² Pa, and still more preferably 1.0×10⁻⁴ Pa to 1.0×10⁻³ Pa. Here, from the viewpoint of supplying sufficient Ga element, the above gas pressure is preferably 1.0×10⁻⁵ Pa or more, more preferably 5.0×10⁻⁵ Pa or more, and still more preferably 1.0×10⁻⁴ Pa or more. In addition, from the viewpoint of supplying sufficient Ga element, in the step 3, the pressure of the gas supplied from the gallium element supply device 1300 is preferably 1.0×10⁻² Pa or less, and more preferably 1.0×10⁻³ Pa or less.

### (Step 4)

The step 4 is a step of epitaxially growing a β-gallium oxide on the single crystal substrate 110 by the above step 2 and step 3.

The internal pressure of the reaction chamber 1100 is preferably 0.001 Pa to 0.01 Pa, and more preferably 0.006 Pa to 0.009 Pa. Here, from the viewpoint of an exhaust capacity of the apparatus, the above internal pressure is preferably 0.001 Pa or more, and more preferably 0.006 Pa or more. In addition, from the viewpoint of a mean free path of oxygen radicals and gallium, the above internal pressure is preferably 0.01 Pa or less, and more preferably 0.009 Pa or less.

The temperature of the single crystal substrate 110, that is, the film formation temperature for epitaxially growing the β-gallium oxide is preferably 0° C. to 600° C., more preferably 0° C. to 500° C., and still more preferably 0° C. to 400° C., and may be 10° C. to 350° C. or 20° C. to 300° C. Here, from the viewpoint of crystal growth, the above film formation temperature is preferably 0° C. or higher, and may be 10° C. or higher, or about room temperature or higher, that is, 20° C. or higher. In addition, from the viewpoint of the growth rate, the above film formation temperature is preferably 600° C. or lower, more preferably 500° C. or lower, still more preferably 400° C. or lower, even more preferably 350° C. or lower, and particularly preferably 300° C. or lower.

The obtained β-gallium oxide film has a proportion of the lattice constant mismatch with the single crystal substrate of preferably 15% or less, more preferably 12% or less, and still more preferably 8% or less. The above proportion is preferably lower, and is generally more than 0%.

The proportion of the lattice constant mismatch has a physically optimal epitaxial relationship with the single crystal substrate due to bond energy between constituent elements of the single crystal and constituent elements of the β-gallium oxide, and is uniquely determined based on the epitaxial relationship.

The β-gallium oxide film has a thickness of preferably 0.5 μm to 50 μm, more preferably 0.8 μm to 30 μm, and still more preferably 1 μm to 20 m. Here, from the viewpoint of withstand voltage for application to a power device and the like, the above thickness is preferably 0.5 μm or more, more preferably 0.8 μm or more, and still more preferably 1 μm or more. In addition, an upper limit thereof is not particularly limited, and from the viewpoint of a film formation rate and a film quality, the thickness of the β-gallium oxide film is preferably 50 μm or less, more preferably 30 μm or less, and still more preferably 20 μm or less.

Although the substrate with a β-gallium oxide film and the production method for the same according to the present embodiment have been described in detail above, other embodiments according to the present embodiment are as follows.

[1]′ A substrate with a β-gallium oxide film, including: a Si single crystal substrate; and a β-gallium oxide film provided on the Si single crystal substrate, in which the β-gallium oxide film is uniaxially oriented.

[2]′ The substrate with a β-gallium oxide film according to the above [1]′, in which the β-gallium oxide film is a single crystal.

[3]′ The substrate with a β-gallium oxide film according to the above [1]′ or [2]′, in which a peak of a β-gallium oxide that belongs to a (100) plane is observed by symmetrical X-ray diffraction.

[4]′ The substrate with a β-gallium oxide film according to any one of the above [1]′ to [3]′, in which the β-gallium oxide film oriented in a (100) plane is provided on the Si single crystal substrate oriented in the (100) plane.

[5]′ The substrate with a β-gallium oxide film according to any one of the above [1]′ to [4]′, in which a [001] direction of the Si single crystal substrate matches a [0-11] direction of the β-gallium oxide film.

[6]′ The substrate with a β-gallium oxide film according to any one of the above [1]′ to [5]′, in which the Si single crystal substrate and the β-gallium oxide film are in direct contact with each other.

[7]′ The substrate with a β-gallium oxide film according to any one of the above [1]′ to [6]′, in which the β-gallium oxide film is provided on the Si single crystal substrate via at least one of a nucleation layer and a surface modification layer.

[8]′ The substrate with a β-gallium oxide film according to any one of the above [1]′ to [7]′, in which the β-gallium oxide film has a thickness of 0.1 μm or more and 50 μm or less.

[9]′ A substrate with a β-gallium oxide film, including:
a gallium nitride single crystal substrate; and
a β-gallium oxide film provided on the gallium nitride single crystal substrate, in which
the β-gallium oxide film is uniaxially oriented.

[10]′ The substrate with a β-gallium oxide film according to the above [9]′, in which the β-gallium oxide film is a single crystal.

[11]′ The substrate with a β-gallium oxide film according to the above [9]′ or [10]′, in which a peak of a β-gallium oxide that belongs to a (100) plane is observed by symmetrical X-ray diffraction.

[12]′ The substrate with a β-gallium oxide film according to any one of the above [9]′ to [11]′, in which the β-gallium oxide film oriented in a (100) plane is provided on the gallium nitride single crystal substrate oriented in a (0001) plane.

[13]′ The substrate with a β-gallium oxide film according to any one of the above [9]′ to [12]′, in which the gallium nitride single crystal substrate and the β-gallium oxide film are in direct contact with each other.

[14]′ The substrate with a β-gallium oxide film according to any one of the above [9]′ to [13]′, in which the β-gallium oxide film is provided on the gallium nitride single crystal substrate via at least one of a nucleation layer and a surface modification layer.

[15]′ The substrate with a β-gallium oxide film according to any one of the above [9]′ to [14]′, in which the β-gallium oxide film has a thickness of 0.1 μm or more and 50 μm or less.

[16]′ A method for producing a substrate with a β-gallium oxide film, including: providing a single crystal substrate in a reaction chamber;
generating plasma from a mixed gas containing oxygen and ozone to dissociate the ozone into oxygen constituent particles, and supplying the oxygen constituent particles to the reaction chamber under a reduced pressure;
supplying a gallium element to the reaction chamber; and epitaxially growing a β-gallium oxide on the single crystal substrate.

[17]′ The method for producing a substrate with a β-gallium oxide film according to the above [16]′, in which a proportion of a lattice constant mismatch between the single crystal substrate and the epitaxially grown β-gallium oxide film is 15% or less.

[18]′ The method for producing a substrate with a β-gallium oxide film according to the above [16]′ or [17]′, in which as the single crystal substrate, a Si single crystal substrate, a gallium nitride single crystal substrate, or a sapphire single crystal substrate is used.

[19]′ The method for producing a substrate with a β-gallium oxide film according to any one of the above [16]′ to [18]′, in which a surface of the single crystal substrate is subjected to an oxygen plasma treatment, and then the β-gallium oxide is epitaxially grown.

[20]′ The method for producing a substrate with a β-gallium oxide film according to any one of the above [16]′ to [19]′, in which the β-gallium oxide is epitaxially grown at a film formation temperature of 600° C. or lower.

[21]′ The method for producing a substrate with a β-gallium oxide film according to any one of the above [16]′ to [20]′, in which a concentration of the ozone is set to 10 vol % or more with respect to a total of the oxygen and the ozone in the mixed gas.

### EXAMPLES

Hereinafter, the present invention is described in detail with reference to Examples, but the present invention is not limited thereto.

(Production of Substrate with β-Gallium Oxide Film)

Using the production apparatus 1000 shown in FIG. 2, a β-gallium oxide film was epitaxially grown on a Si single crystal substrate according to the following procedure, thereby obtaining a substrate with a β-gallium oxide film.

Specifically, first, the Si single crystal substrate was washed with an organic solvent, then washed with an acid, and then dried. Next, the Si single crystal substrate was placed on the substrate disposition portion 1200 with the (100) plane being the top surface, and was supported by the susceptor 1210.

The temperature of the Si single crystal substrate was increased to 300° C., and while maintaining the temperature, the pressure in the reaction chamber 1100 was reduced to 8.0×10⁻³ Pa.

On the other hand, with respect to an oxygen gas supplied from the oxygen gas supply unit, using the ozonizer 1700, a mixed gas containing oxygen and ozone, in which the concentration of ozone was 28 vol % with respect to the total of oxygen and ozone, was supplied into the oxygen element supply device 1400. At the same time, an Ar gas was also supplied from the inert gas supply unit 1600 into the oxygen element supply device 1400. A ratio of the mixed gas containing oxygen and ozone to the Ar gas was 1:4.

Thereafter, O₂ and O₃ were supplied from the oxygen element supply device 1400 to the above reaction chamber 1100 under a reduced pressure at a flow rate of 8 sccm O₂+O₃, and at the same time, an oxygen plasma treatment was performed on the Si single crystal substrate for 15 minutes at a plasma output of 1000 W to form a surface modification layer. Thereafter, Ga was further supplied from the gallium element supply device 1300 to the reaction chamber 1100 at a pressure of 1.13×10⁻⁴ Pa, and a β-gallium oxide film was grown for 60 minutes. With the above, a Si single crystal substrate with a gallium oxide film was obtained.

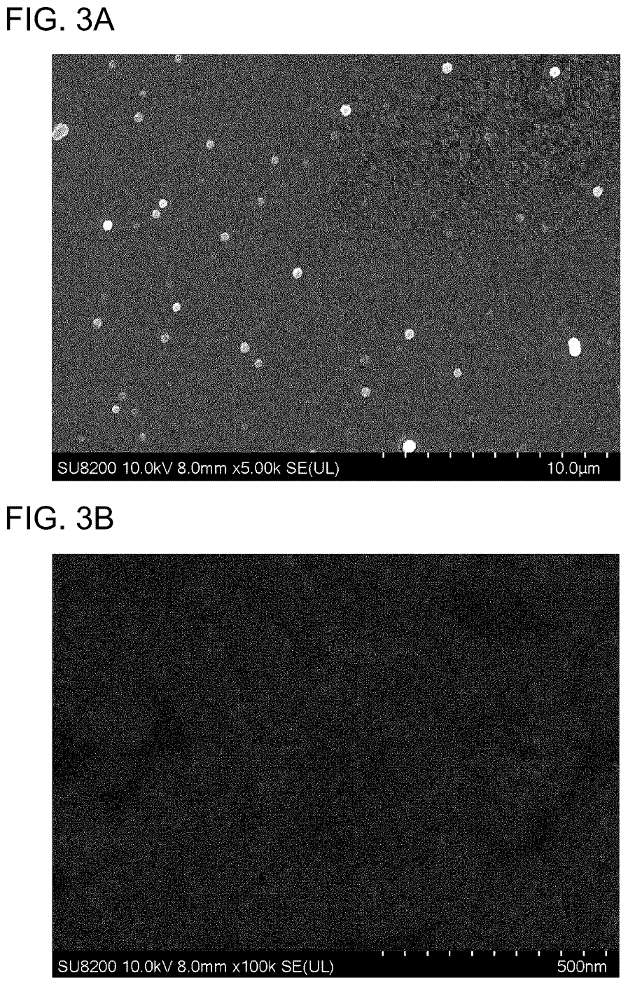

FIG. 3A and FIG. 3B show scanning electron microscope photographs of a surface of the Si single crystal substrate with a gallium oxide film obtained above. FIG. 3A is at a magnification of 5,000 times, and FIG. 3B is at a magnification of 100,000 times. From both, it is found that the surface of the grown gallium oxide film was very clean and had high flatness.

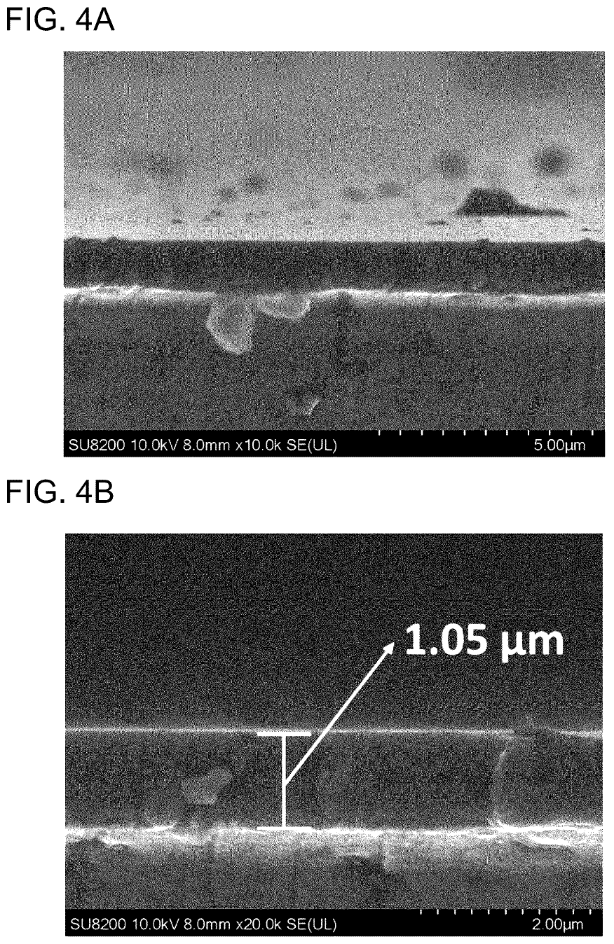

FIG. 4A and FIG. 4B show scanning electron microscope photographs of a cross section of the Si single crystal substrate with a gallium oxide film obtained above. FIG. 4A is at a magnification of 10,000 times, and FIG. 4B is at a magnification of 20,000 times. From both, it is found that the thickness of the grown gallium oxide film was measured to be 1.05 μm, and the film formation rate was 1.05 m/hr, i.e., 17.5 nm/min.

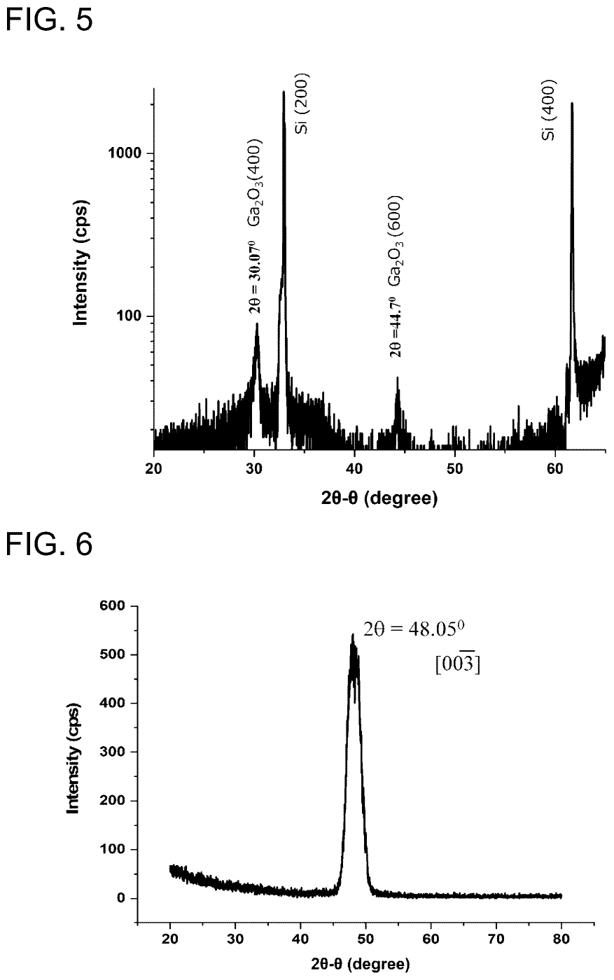

The obtained Si single crystal substrate with a gallium oxide film was subjected to symmetrical X-ray diffraction measurement. CuKα rays were used as a ray source, a Si surface was irradiated with X-rays at an incident angle of a Bragg diffraction angle θ, and the diffracted X-rays were detected by rotating a detector at θ-2θ to measure the diffraction angle. The obtained pattern is shown in FIG. 5, where the horizontal axis is 20-0° and the vertical axis is intensity. In addition to a peak of a Si (200) plane and a peak of a Si (400) plane, a peak of the (400) plane of the β-gallium oxide was observed at 2θ=30.07°, and a peak of the (600) plane of the β-gallium oxide was observed at 2θ=44.7°. From this, it is clear that the gallium oxide film in the obtained Si single crystal substrate with a gallium oxide film was a 3-gallium oxide single crystal film.

The Si single crystal substrate with a gallium oxide film was subjected to in-plane X-ray diffraction measurement. CuKα rays were used as a ray source, the Si surface was irradiated with X-rays at an incident angle of a minute angle of 0.3°, and the X-rays diffracted in a direction perpendicular to the normal direction of the Si single crystal substrate were detected by rotating a detector at θ-2θ to measure the diffraction angle.

The obtained pattern is shown in FIG. 6, where the horizontal axis is 20-0° and the vertical axis is intensity. When a direction of 0=0° was about 260 clockwise from the [010] direction of Si, a peak of a (00-3) plane of the β-gallium oxide was observed at 2θ=48.05°. From this, it is clear that the β-gallium oxide single crystal has been more reliably formed as a gallium oxide film, and that there was an epitaxial relationship between the Si single crystal substrate and the β-gallium oxide film.

From the results of the above X-ray diffraction measurement, the epitaxial relationship between the Si single crystal substrate oriented in the (100) plane and a β-gallium oxide single crystal thin film epitaxially grown on the surface is estimated to be as follows.
Si (100)//β-Ga₂O₃ (100)
Si [001]//β-Ga₂O₃ [0-11]

The growth of the β-gallium oxide single crystal film on the Si single crystal substrate oriented in the (100) plane having such an epitaxial relationship has never been reported before, and this is the first time it has been achieved.

The β-gallium oxide single crystal is a monoclinic single crystal, and has a lattice constant of a=12.214 Å, b=3.0371 Å, and c=5.7981 Å. The angles between lattices are also different in respective directions, with α=γ=900 and β=103.83°, the lattice constants are different, and the crystal structure has the a axis oblique to the c axis. Due to this unique crystal structure, the β-gallium oxide single crystal is epitaxially grown on the Si single crystal substrate in a direction in which a lattice mismatch rate with Si having a simple diamond crystal structure is minimized. The present invention has been completed based on this new finding.

Based on the epitaxial relationship obtained from the results of the above symmetrical X-ray diffraction measurement and in-plane X-ray diffraction measurement, the lattice mismatch between the Si single crystal substrate oriented in the (100) plane and the β-gallium oxide single crystal film was calculated. The lattice mismatch can be calculated, for example, based on a ratio between the lattice constant of the Si single crystal substrate and the lattice constant of the β-gallium oxide single crystal film projected onto a certain direction of the Si single crystal substrate.

Specifically, the lattice constant of the β-gallium oxide single crystal film in the [001] direction is projected onto the [001] direction of the Si single crystal substrate, and a difference thereof is divided by the lattice constant of the Si single crystal substrate in the [001] direction. Similarly, twice of the lattice constant of the β-gallium oxide single crystal film in a [010] direction is projected onto the [010] direction of the Si single crystal substrate, and a difference thereof is divided by the lattice constant of the Si single crystal substrate in the [010] direction.

Assuming that the [001] direction of the Si single crystal substrate and the [0-11] direction of the β-gallium oxide single crystal film were completely parallel, the lattice mismatch in the [001] direction of the Si single crystal substrate was estimated to be 5.4%, and the lattice mismatch in the [010] direction of the Si single crystal substrate was estimated to be 0.9%. Due to the arrangement of Si atoms and β-gallium oxide atoms, the [001] direction of the Si single crystal substrate and the [0-11] direction of the β-gallium oxide single crystal film might be slightly misaligned. As a result, the lattice mismatch was very small, and the reason why a high-quality β-gallium oxide single crystal film could be grown on the Si single crystal substrate oriented in the (100) plane has been scientifically clarified.

Next, in producing a Si single crystal substrate with a β-gallium oxide film, AFM images of the surface of the Si single crystal substrate were observed before and after an oxygen plasma treatment was performed on the Si single crystal substrate for 15 minutes.

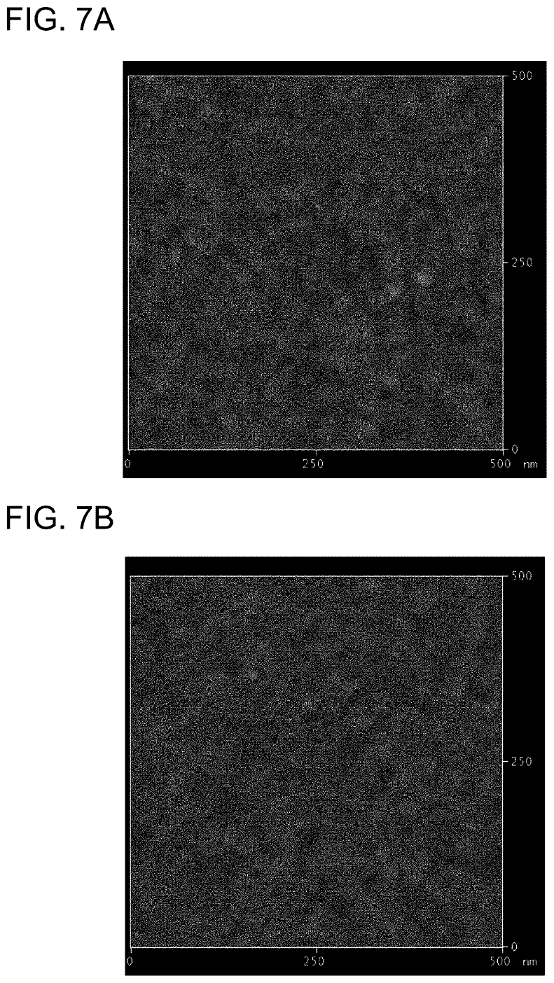

The results are shown in FIG. 7A and FIG. 7B. FIG. 7A is the AFM image of the Si single crystal substrate before the oxygen plasma treatment is performed, and FIG. 7B is the AFM image of the Si single crystal substrate 15 minutes after the oxygen plasma treatment is performed.

The surface roughness before the oxygen plasma treatment was performed is 0.152 nm, whereas the surface roughness after the treatment was 0.131 nm. From this, it is found that the surface of the Si single crystal substrate was flatter due to the oxygen plasma treatment.

From the above, the production method according to the present embodiment has made it possible to produce a β-gallium oxide film on a Si single crystal substrate without a buffer layer. More specifically, a (100)-oriented β-gallium oxide single crystal film could be epitaxially grown on a (100)-oriented Si single crystal substrate.

The β-gallium oxide film had a very low growth temperature at 300° C., a very fast film formation rate, and a large thickness. Further, the surface of the β-gallium oxide film was very smooth and had good flatness, and it was a single crystal film having good crystallinity.

In the related art, there have been no reports of a β-gallium oxide film being able to grow on a (100)-oriented Si single crystal substrate without a buffer layer. Further, the fast growth rate, the low film formation temperature, and the good flatness and crystallinity achieved in the present embodiment are surprising, and the effects of the present invention are clear.

Instead of the Si single crystal substrate, a gallium nitride single crystal substrate was used, and a gallium oxide film was formed on the surface in the same manner as above. The obtained gallium nitride single crystal substrate with a gallium oxide film was also subjected to symmetrical X-ray diffraction measurement. A diffraction peak was obtained for the Ga₂O₃ (400) plane at a Bragg diffraction angle of 2θ=30.070 and for the Ga₂O₃ (600) plane at a Bragg diffraction angle of 2θ=44.7°, and the gallium oxide film was found to be a β-gallium oxide single crystal film. Specifically, a β-gallium oxide single crystal film oriented in the (100) plane was formed on a gallium nitride single crystal substrate oriented in the (0001) plane. In addition, the flatness of the surface of the β-gallium oxide single crystal film was observed by observation using a scanning electron microscope, and the thickness of the β-gallium oxide film was found to be 0.9 μm to 1.0 μm by cross-sectional observation.

Although the present invention has been described in detail with reference to specific embodiments, it is apparent to those skilled in the art that various changes and modifications can be made without departing from the spirit and scope of the present invention. The present application is based on a Japanese Patent Application (No. 2022-050538) filed on Mar. 25, 2022, and a Japanese Patent Application (No. 2022-075480) filed on Apr. 28, 2022, and the contents of which are incorporated herein by reference.

### INDUSTRIAL APPLICABILITY

In the present invention, instead of a gallium oxide single crystal substrate in the related art, a low-cost Si single crystal substrate or other single crystal substrate can be used to produce a β-gallium oxide single crystal film thereon. In addition, the β-gallium oxide single crystal film can be obtained at a low temperature and at a fast film formation rate with any desired thickness, and further, the surface flatness and crystallinity of the obtained β-gallium oxide film are good. Therefore, it has high industrial applicability.

### REFERENCE SIGNS LIST

100: substrate with β-gallium oxide film
110: single crystal substrate
110a: first main surface
120: β-gallium oxide film
1000: production apparatus
1100: reaction chamber
1200: substrate disposition portion
1210: susceptor
1220: heating device
1300: gallium element supply device
1310, 1410: shutter
1400: oxygen element supply device
1450: plasma generation unit
1500: oxygen gas supply unit
1600: inert gas supply unit
1700: ozonizer
1810: oxygen gas supply pipe
1820, 1840, 1860: mass flow controller
1830: ozone-oxygen mixed gas supply pipe
1850: inert gas supply pipe
1870: mixed gas supply pipe

1. A substrate with a β-gallium oxide film, comprising:
a Si single crystal substrate; and
a β-gallium oxide film provided on the Si single crystal substrate,
wherein the β-gallium oxide film is uniaxially oriented.

2. The substrate with a β-gallium oxide film according to claim 1, wherein the β-gallium oxide film is a single crystal.

3. The substrate with a β-gallium oxide film according to claim 1, wherein a peak of a β-gallium oxide that belongs to a (100) plane is observed by symmetrical X-ray diffraction.

4. The substrate with a β-gallium oxide film according to claim 1, wherein the β-gallium oxide film oriented in a (100) plane is provided on the Si single crystal substrate oriented in the (100) plane.

5. The substrate with a β-gallium oxide film according to claim 1, wherein a [001] direction of the Si single crystal substrate matches a [0-11] direction of the β-gallium oxide film.

6. The substrate with a β-gallium oxide film according to claim 1, wherein the Si single crystal substrate and the β-gallium oxide film are in direct contact with each other.

7. The substrate with a β-gallium oxide film according to claim 1, wherein the β-gallium oxide film is provided on the Si single crystal substrate via at least one of a nucleation layer and a surface modification layer.

8. The substrate with a β-gallium oxide film according to claim 1, wherein the β-gallium oxide film has a thickness of 0.1 μm or more and 50 μm or less.

9. A substrate with a β-gallium oxide film, comprising:
a gallium nitride single crystal substrate; and
a β-gallium oxide film provided on the gallium nitride single crystal substrate,
wherein the β-gallium oxide film is uniaxially oriented.

10. The substrate with a β-gallium oxide film according to claim 9, wherein the β-gallium oxide film is a single crystal.

11. The substrate with a β-gallium oxide film according to claim 9, wherein a peak of a β-gallium oxide that belongs to a (100) plane is observed by symmetrical X-ray diffraction.

12. The substrate with a β-gallium oxide film according to claim 9, wherein the β-gallium oxide film oriented in a (100) plane is provided on the gallium nitride single crystal substrate oriented in a (0001) plane.

13. The substrate with a β-gallium oxide film according to claim 9, wherein the gallium nitride single crystal substrate and the β-gallium oxide film are in direct contact with each other.

14. The substrate with a β-gallium oxide film according to claim 9, wherein the β-gallium oxide film is provided on the gallium nitride single crystal substrate via at least one of a nucleation layer and a surface modification layer.

15. The substrate with a β-gallium oxide film according to claim 9, wherein the β-gallium oxide film has a thickness of 0.1 μm or more and 50 μm or less.

16. A method for producing a substrate with a β-gallium oxide film, comprising:
providing a single crystal substrate in a reaction chamber;
generating plasma from a mixed gas containing oxygen and ozone to dissociate the ozone into oxygen constituent particles, and supplying the oxygen constituent particles to the reaction chamber under a reduced pressure;
supplying a gallium element to the reaction chamber; and
epitaxially growing a β-gallium oxide on the single crystal substrate.

17. The method for producing a substrate with a β-gallium oxide film according to claim 16, wherein a proportion of a lattice constant mismatch between the single crystal substrate and the epitaxially grown β-gallium oxide film is 15% or less.

18. The method for producing a substrate with a β-gallium oxide film according to claim 16, wherein as the single crystal substrate, a Si single crystal substrate, a gallium nitride single crystal substrate, or a sapphire single crystal substrate is used.

19. The method for producing a substrate with a β-gallium oxide film according to claim 16, wherein a surface of the single crystal substrate is subjected to an oxygen plasma treatment, and then the β-gallium oxide is epitaxially grown.

20. The method for producing a substrate with a β-gallium oxide film according to claim 16, wherein the β-gallium oxide is epitaxially grown at a film formation temperature of 600° C. or lower.

21. The method for producing a substrate with a β-gallium oxide film according to claim 16, wherein a concentration of the ozone is set to 10 vol % or more with respect to a total of the oxygen and the ozone in the mixed gas.
